(19) United States
(12) Patent Application Publication
(10) Pub. No.: US 2014/0152338 A1
(43) Pub. Date: Jun. 5, 2014

(54) ELECTRONIC DEVICE RELIABILITY MEASUREMENT SYSTEM AND METHOD

(71) Applicant: Electronics and Telecommunications Research Institute, Daejeon (KR)

(72) Inventors: Jongmin LEE, Daejeon (KR); Byoung-Gue Min, Daejeon (KR); Chull Won Ju, Daejeon (KR)

(73) Assignee: Electronics and Telecommunications Research Institute, Daejeon (KR)

(21) Appl. No.: 13/950,939

(22) Filed: Jul. 25, 2013

(30) Foreign Application Priority Data
Dec. 4, 2012 (KR) 10-2012-0139737

(51) Int. Cl. G01R 31/26

(52) U.S. Cl. CPC G01R 31/2608; G01R 31/2621; G01R 31/2632
USPC 324/762.07; 324/762.01; 324/762.09; 324/762.08

(57) ABSTRACT

Provided is a low-cost and high-efficient system for measuring reliability of an electronic device. According to the present invention, a single input power source for applying power to an input terminal of a plurality of electronic device samples and a single output power source for applying power to an output terminal of the plurality of electronic device samples are provided. Further, an input switch having first switches of which the number corresponds to the number of the plurality of electronic device samples, the input switch being installed between the input power source and the input terminal so that the first switches are selectively switched to apply input power; and an output switch having second switches of which the number corresponds to the number of the plurality of electronic device samples, the output switch being installed between the output power source and the output terminal so that the second switches are selectively switched to apply output power are provided.

### CROSS-REFERENCE TO RELATED APPLICATIONS

This U.S. non-provisional patent application claims priority under 35 U.S.C. §119 of Korean Patent Application No. 10-2012-0139737, filed on Dec. 4, 2012, the entire contents of which are hereby incorporated by reference.

### BACKGROUND OF THE INVENTION

The present invention disclosed herein relates to a measurement system, and more particularly, to an electronic device reliability measurement system and method for measuring reliability of an electronic device such as a transistor.

In general, an electronic device such as a bipolar junction transistor (BJT) or a field effect transistor (FET) may be tested to guarantee reliability.

Such a reliability test of an electronic device may be classified into a case where a bias is applied and a case where a bias is not applied. Considering the statistical significance of a test result, at least a certain number of samples are tested.

### SUMMARY OF THE INVENTION

The present invention provides a system and method for measuring reliability of an electronic device.

The present invention also provides a system and method for measuring reliability of an electronic device through a more efficient test.

Embodiments of the present invention provide electronic device reliability measurement systems including: a single input power source for applying power to an input terminal of a plurality of electronic device samples; a single output power source for applying power to an output terminal of the plurality of electronic device samples; an input switch having first switches of which the number corresponds to the number of the plurality of electronic device samples, the input switch being installed between the input power source and the input terminal so that the first switches are selectively switched to apply input power; and an output switch having second switches of which the number corresponds to the number of the plurality of electronic device samples, the output switch being installed between the output power source and the output terminal so that the second switches are selectively switched to apply output power.

In other embodiments of the present invention, electronic device reliability measuring methods include: providing a single input power source for applying power to an input terminal of a plurality of electronic device samples and a single output power source for applying power to an output terminal of the plurality of electronic device samples; installing an input switch having a plurality of first switches and selectively switched so as to apply input power to the input terminal and an output switch having a plurality of second switches and selectively switched so as to apply output power to the output terminal; and applying the input power and the output power to at least one of the plurality of electronic device samples by selectively switching the first switches of the input switch and the second switches of the output switch, thereby testing reliability of the plurality of electronic device.

In still other embodiments of the present invention, electronic device reliability measuring methods for performing a reliability test on electronic device samples by monitoring output voltages and output currents of the electronic device samples are performed by applying a single input power source to the electronic device sample or one of the electronic device samples through at least one of first switches, and applying a single output power source to the electronic device sample or one of the electronic device samples through at least one of second switches.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a schematic block diagram illustrating a typical system for measuring reliability of an electronic device;

FIG. 2 is a block diagram illustrating a system for measuring reliability of an electronic device according to an embodiment of the present invention;

FIG. 3 is a flowchart illustrating a process of reliability measurement of the system of FIG. 2; and

FIG. 4 is an exemplary graph illustrating a monitoring output generated according to the reliability measurement of the system of FIG. 2.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the present disclosure, when it is mentioned that some devices or lines are connected to a target device block, it should be understood that the devices or lines may be directly or indirectly connected to the target device block via another device.

In the drawings, like reference numerals refer to like elements. In some drawings, connection relationships between devices, circuit bocks, and lines are illustrated just for efficient description, and other devices, device blocks, or circuit blocks may be further provided.

The embodiments described herein may include complementary embodiments thereof. It should be noted that specific operations and detailed internal circuits of a typical electronic device reliability measurement system are not provided in order not to obscure the present invention.

The development of various communication technologies and semiconductor technologies has remarkably changed modern society and has provided various conveniences. This technology development started with the development of semiconductor devices in the early 20th century. Electronic products or communication products include various electronic devices.

Before putting such products in the market, reliability of the products should be measured. The reliability of the products should satisfy a certain level of standard so that the products have commercial values.

The reliability indicates possibility that a test sample will perform required functions for a given period of time under a given condition. Here, the sample includes a single item that may be individually considered, a component, a device, a subsystem, a function unit, equipment, or a system.

A reliability test includes a performance test, an environment test, a failure rate test, and a life test. Conditions and decision criteria for the tests are differentiated according to types of the tests and types of samples.

The reliability test of an electronic device is carried out according to a type of a typical reliability test. That is, a condition and criterion of the test may be changed according to whether a type of the device is a FET, a BJT, a silicon (Si)-based device, or a device of compound such as GaAs, InP, and GaN.

In particular, a failure rate test and an accelerated life test, from among various types of the reliability test, are frequency carried out. To perform the failure rate test for guaranteeing a failure rate of a product, a sample size and a test period are determined by determining a level of reliability. The accelerated life test refers to any test performed under a condition that is severer than a condition of use in order to shorten time. According to this test, test data are analyzed to estimate a life-stress relation formula. From this relation formula, a life under the condition of use may be estimated.

The reliability test of an electronic device may be classified into a case where a bias is applied and a case where a bias is not applied, and more than a certain number of multiple samples are used for the test.

To measure reliability, the number of samples of the same type is determined in consideration of a level of reliability, and an operation condition is determined in consideration of a breakdown upper limit and an operation upper limit of a device.

When such a condition is determined, according to a typical technique, a test jig suitable for each sample is used, and a power source is connected to each jig in order to perform the test. That is, if N number of samples are to be measured, respective power sources for operating the N number of samples are necessary. If the power sources do not have measuring functions, additional measuring devices are necessary.

The number and types of required power sources are changed according to a type of an electronic device. In the case where the electronic device is a two-port device such as a diode, one power source and measuring device are necessary. However, in the case where the electronic device is a three-port device such as a BJT or FET, a power source and measuring device are necessary for each of input and output. Therefore, as the number of samples increases, a necessary system configuration becomes more complicated, causing an increase in a cost.

When a company or research institute performs a reliability test, several hundred samples should be tested in order to have a reliability level of about 95% or more. Further, since a test jig for each sample is additionally required, the cost of a measurement system is mainly determined according to the power source and measuring device for driving a sample. Moreover, in the case of testing an RF device, when the reliability test is performed while applying an RF signal, a plurality of expensive devices are required.

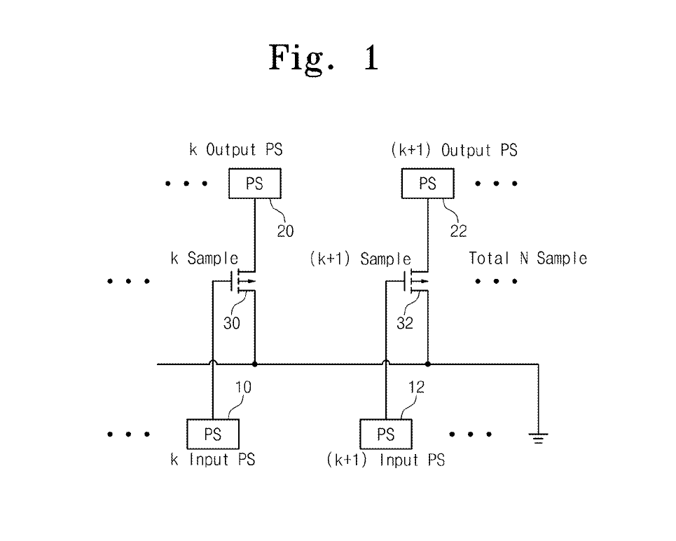

FIG. 1 is a schematic block diagram illustrating a typical system for measuring reliability of an electronic device.

To simply illustrate a configuration of the system, FIG. 1 exemplarily illustrates only two devices. Here, it is assumed that the number of samples is N (N is a natural number not less than 2). FIG. 1 illustrates a kth sample 30 and a next (k+1)th sample 32.

When it is assumed that the electronic device sample is a FET that is a three-port device, the three ports may be respectively referred to as a source, a drain, and a gate. However, the sample may be any electronic device.

As illustrated in FIG. 1, in order to drive the kth FET 30, a power for applying a gate voltage to an input terminal, i.e. a gate, and a power source for applying a drain voltage to an output terminal, i.e. a drain, are necessary.

In FIG. 1, the power sources for driving the kth sample 30 are respectively represented by k input PS 10 and a k output PS 20, and the power sources for driving the (k+1)th sample 32 are respectively represented by k+1 input PS 12 and a k+1 output PS 22.

The sources of all the samples 30 and 32 are connected to a common ground.

As illustrated in FIG. 1, two power sources are necessary for testing each sample. Although not illustrated in FIG. 1, in the case where a power source does not have a multimeter function, a current meter for measuring characteristics of an electronic device may be added to each of input and output terminals. In this case, four sources and a measuring device are needed to test one sample. Thus, in order to test N number of samples, necessary pieces of equipment are four times the number of samples.

Accordingly, a system configuration becomes very complicated and a space for the equipment is limited. Moreover, the cost of constructing the system also increases.

Moreover, when individual systems are constructed for DC measurement, RF measurement, and power measurement in the reliability system, the cost of constructing the system may more greatly increase.

Therefore, embodiments of the present invention provide a technology to overcome the limitation on the construction of the system for measuring reliability of an electronic device such as a BJT and a FET.

In particular, a technology for efficiently performing a reliability test on a plurality of the same samples at a low cost will be described.

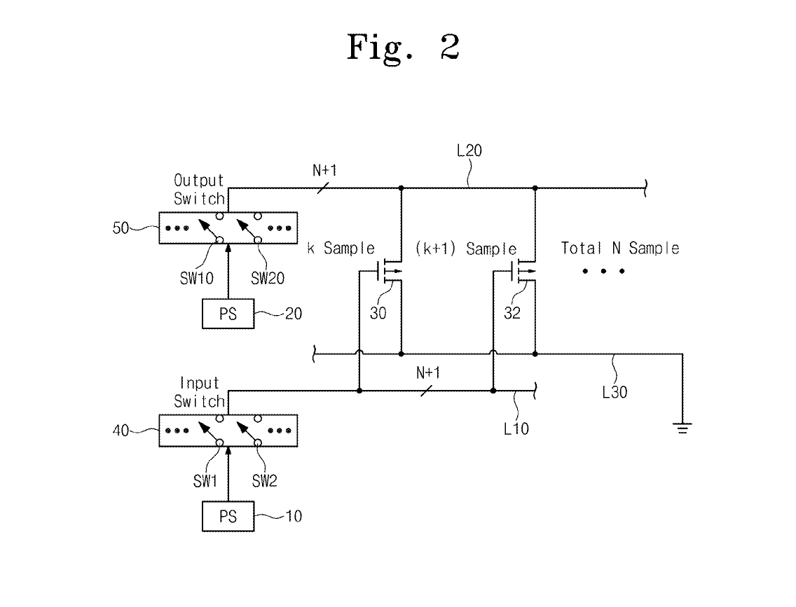

FIG. 2 is a block diagram illustrating an electronic device reliability measurement system according to an embodiment of the present invention.

Referring to FIG. 2, the electronic device reliability measurement system includes: a single input power source 10 for applying power to an input terminal L10 of a plurality of electronic device samples 30 and 32; a single output power source 20 for applying power to an output terminal L20 of the plurality of electronic device samples; an input switch 40 which has first switches SW1 and SW2 of which the number corresponds to that of the plurality of electronic device samples, and is installed between the input power source 10 and the input terminal L10 so that the first switches are selectively switched to apply input power; and an output switch 50 which has second switches SW10 and SW20 of which the number corresponds to that of the plurality of electronic device samples, and is installed between the output power source 20 and the output terminal L20 so that the second switches are selectively switched to apply output power.

For simple illustration, FIG. 2 illustrates only two electronic devices, i.e. the samples 30 and 32. That is, FIG. 2 illustrates a kth sample 30 and a next (k+1)th sample 32 among N number of samples.

According to the configuration of FIG. 2, an individual power source and measuring device for driving each sample is not additionally necessary. That is, according to the configuration of FIG. 1, system complexity greatly increases, causing limitations in terms of cost and space. However, the configuration of FIG. 2 may overcome such limitations.

That is, to simplify the system configuration in FIG. 2, the input switch is installed on the input terminal and the output switch is installed on the output terminal so that the power sources may be shared by the plurality of samples.

By virtue of an switching operation of the input switch 40, only one input power source 10 is installed, and, by virtue of an switching operation of the output power source 50, only one output power source 20 is installed. As described above, although two switches are added, only one power source is arranged to apply a bias to each of the input and output terminals of the samples. Therefore, the number of power sources and measuring devices is reduced. As a result, the system configuration is simplified, and the cost of constructing the system is reduced. Although not illustrated in FIG. 2, if a multimeter function is added to the power source, an additional measuring device may not be necessary. Further, for more precise measurement, a semiconductor analyzer may be additionally installed.

In FIG. 2, in the input switch 40 or output switch 50, the number of ports of switches may be greater than N in the case where the number of the samples is N. In the case where the switch port number is greater than N, a bias may be individually applied to each sample. Further, in FIG. 2, the input line L10 may be a single common line or a plurality of individual lines. Likewise, in FIG. 2, the input line L20 may be a single common line or a plurality of individual lines.

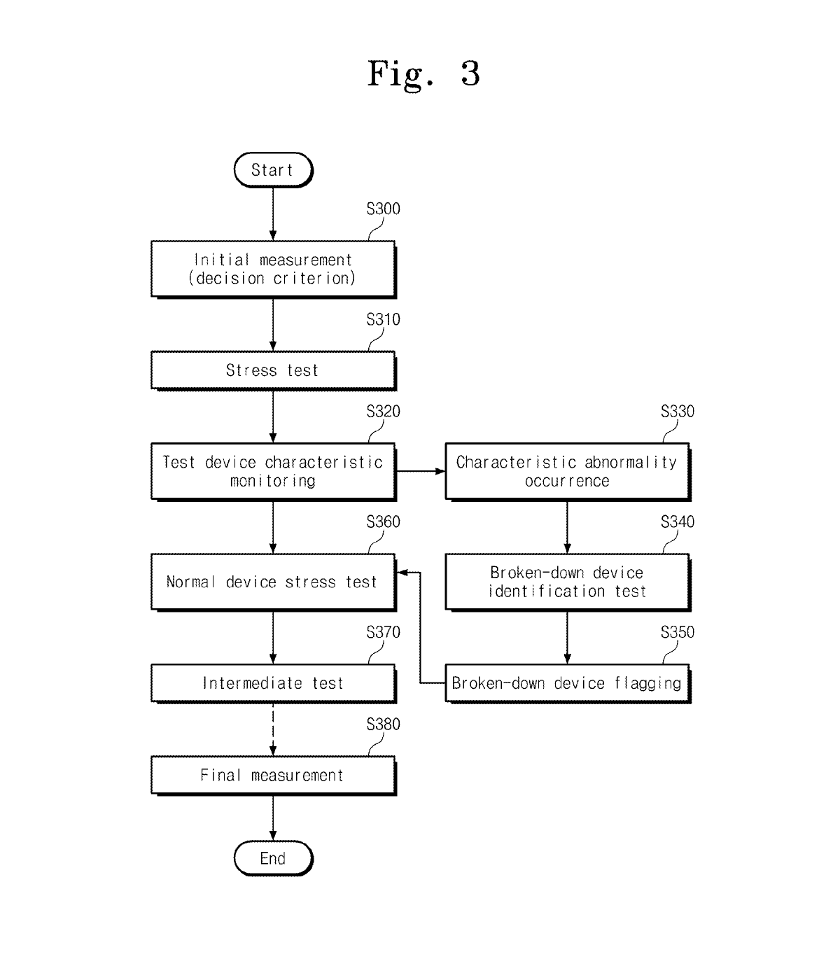

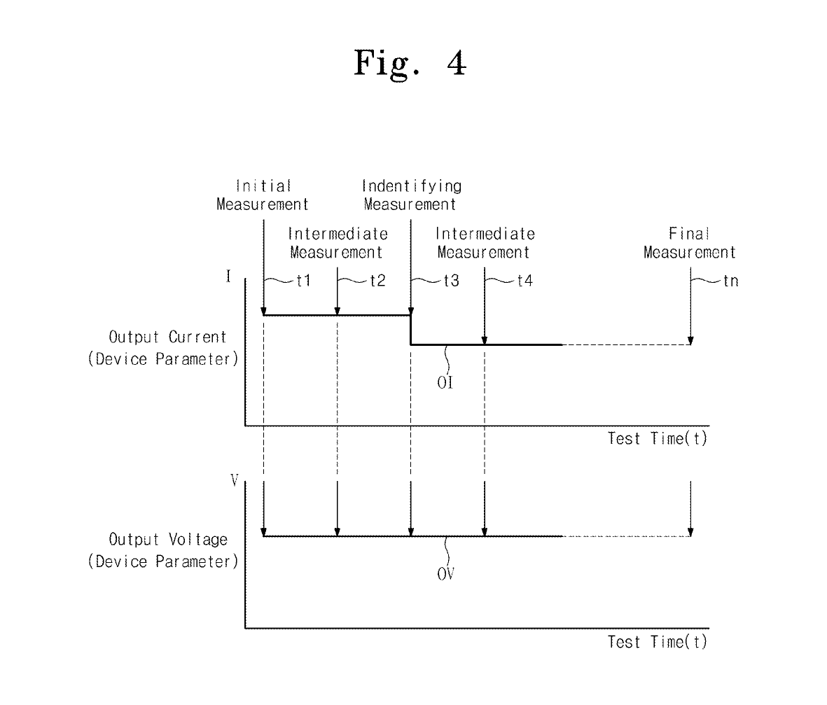

FIG. 3 is a flowchart illustrating a process of reliability measurement of the system of FIG. 2, and FIG. 4 is an exemplary graph illustrating a monitoring output generated according to the reliability measurement of the system of FIG. 2.

FIG. 3 exemplarily illustrates the process of the reliability measurement through operations S300 to S380.

A test is started after selecting samples, determining the number of the samples, and mounting the samples on the measurement system. Here, a condition and method of the test are determined. In addition, the sample may be any type of an electronic device. Here, for convenience, it is assumed that an FET device is tested.

In operation S300, an initial measurement is performed. The initial measurement is performed for a decision criterion. Here, if the number of all samples is N, characteristics of each of the N number of samples may be measured. Here, in order to measure the kth sample 30, the kth switches SW1 and SW10 of the input and output switches 40 and 50 are turned on, and the other switches are turned off. Data initially measured in this manner are stored in a memory of the system and are used as criterion data of device breakdown.

In operation S310, a stress test is performed under the determined test condition. Here, there are various types of the stress test, but a DC stress accelerated test is exemplarily performed. Since it is assumed that the sample is a FET device, a gate voltage of the input terminal and a drain voltage of the output terminal are applied to the sample through the respective power sources. In this case, values of currents flowing through the input and output terminals are read as measurement values. In the stress test, all the switches of the input and output terminals for the N number of samples are turned on so that a bias may be simultaneously applied to all the samples.

In operation S320, a constant voltage is applied from the input and output terminals in order to monitor device characteristic values of the N number of samples. According to a device type and test method, the characteristic values of an electronic device to be monitored may be changed. Here, it is assumed that values of total currents flowing through the input and output terminals are monitored.

In operation S330, it is monitored whether characteristic abnormality occurs. When a stress test on an electronic device is performed, a characteristic parameter value of the device is gradually changed and may be represented by a typical bathtub curve. However, if any of devices being tested is broken down, the stress test may not be normally performed, and the test may be stopped to screen the broken down device. That is, for example, in the case of the system according to an embodiment of the present invention, if it is assumed that any one of the samples being monitored has an open circuit, a current does not flow through the device any more. The current value being monitored is rapidly changed (reduced) as indicated at a time point t3 of FIG. 4.

FIG. 4 illustrates, in a graphic form, a device parameter change that may occurs during the stress test, and measurement for identifying the broken down device.

In FIG. 4, a horizontal axis represents a test time, and a vertical axis represents an output current and an output voltage. A graph OI illustrates a monitored output current, and a graph OV illustrates a monitored output voltage.

In FIG. 4, when a current value is rapidly reduced at the time point t3, the stress test is stopped and the broken down device may be identified through the indentifying measurement. If the device has an open circuit, as illustrated in FIG. 4, the current value is rapidly changed, but a voltage value does not vary. On the contrary, if the device is short-circuited, both the current value and the voltage value are rapidly changed. Here, a criterion of the rapid change may be determined in consideration of the characteristics and number of the samples initially tested. The stress test may be stopped by turning off all the power sources 10 and 20 and switches 40 and 50.

In operation S340, a broken-down device identifying test is performed. The broken-down device identifying test is performed to detect the broken-down device after the stress test is stopped. The broken-down device identifying test may be performed in the same manner as the initial measurement. That is, if the number of all samples is N, characteristics of each of the N number of samples are measured. Here, in order to measure the kth sample, the kth switch is turned on and the other switch is turned off so that characteristics of only the kth sample are measured. After measuring each sample, a result of the measurement is compared with most recently stored data so as to identify whether the device is broken down.

In operation S340, the broken-down device is flagged. After detecting the broken-down device through the broken-down device identifying test, broken-down device flagging is performed. The flagged broken-down device is excluded from a later stress test.

In operation S360, a normal device stress test is performed. After performing the broken-down device flagging in operation S350, the stress test is continuously performed on the other normal devices in operation S360.

In operation S370, intermediate measurement is performed. When the test is started, a time for the intermediate measurement may be set so that the intermediate measurement may be performed in the intervals of the stress test. For instance, in the case where the stress test is performed for 1000 hours, the intermediate measurement time may be set to be 24 hours, 48 hours, 96 hours, 192 hours, 384 hours, 768 hours, or the like. In the case of the intermediate measurement, the stress test may be stopped so as to measure characteristics of each device by using the switches 40 and 50 in the same manner as the initial measurement and store data. In this case, a result of the intermediate measurement is compared with that of the initial measurement, and, when the device characteristic value is changed, the device is flagged as a broken-down device to be excluded from a later stress test.

In operation S380, final measurement is performed. When a set stress test time is reached, the stress test is finished. Here, after measuring final characteristics of each device, the measured data are stored.

When the measurement of operation S380 is completed, the test is finished. Here, the entire test is finished, and all equipment and switches are turned off.

According to the system configuration and test process of the present invention, the reliability test on a plurality of electronic devices is more efficiently performed with simple equipment.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A electronic device reliability measurement system comprising:
a single input power source for applying power to an input terminal of a plurality of electronic device samples;
a single output power source for applying power to an output terminal of the plurality of electronic device samples;
an input switch having first switches of which the number corresponds to the number of the plurality of electronic device samples, the input switch being installed between the input power source and the input terminal so that the first switches are selectively switched to apply input power; and
an output switch having second switches of which the number corresponds to the number of the plurality of electronic device samples, the output switch being installed between the output power source and the output terminal so that the second switches are selectively switched to apply output power.

2. The electronic device reliability measurement system of claim 1, wherein the number of the input power source is one in the case where the number of the plurality of electronic device samples is increased.

3. The electronic device reliability measurement system of claim 1, wherein the number of the output power source is one in the case where the number of the plurality of electronic device samples is increased.

4. The electronic device reliability measurement system of claim 1, wherein the plurality of electronic device samples are field effect transistors.

5. The electronic device reliability measurement system of claim 1, wherein the plurality of electronic device samples are bipolar junction transistors.

6. The electronic device reliability measurement system of claim 1, wherein the plurality of electronic device samples are diodes.

7. The electronic device reliability measurement system of claim 1, wherein, in the case where a kth sample among the plurality of electronic device samples is tested, a kth switch among the first switches is switched.

8. The electronic device reliability measurement system of claim 1, wherein, in the case where a kth sample among the plurality of electronic device samples is tested, a kth switch among the second switches is switched.

9. The electronic device reliability measurement system of claim 1, wherein a test on the plurality of electronic device samples comprises a DC measurement on the samples.

10. The electronic device reliability measurement system of claim 1, wherein a test on the plurality of electronic device samples comprises an RF measurement on the samples.

11. The electronic device reliability measurement system of claim 1, wherein a test on the plurality of electronic device samples comprises a power characteristic measurement on the samples.

12. A electronic device reliability measuring method comprising:
providing a single input power source for applying power to an input terminal of a plurality of electronic device samples and a single output power source for applying power to an output terminal of the plurality of electronic device samples;
installing an input switch having a plurality of first switches and selectively switched so as to apply input power to the input terminal and an output switch having a plurality of second switches and selectively switched so as to apply output power to the output terminal; and
applying the input power and the output power to at least one of the plurality of electronic device samples by selectively switching the first switches of the input switch and the second switches of the output switch, thereby testing reliability of the plurality of electronic device.

13. The electronic device reliability measuring method of claim 12, wherein the testing of reliability comprises performing a initial measurement and a stress test and then monitoring characteristics of the electronic device sample being tested.

14. The electronic device reliability measuring method of claim 13, wherein the monitoring of characteristics of the electronic device sample comprises identifying occurrence of characteristic abnormality, performing a broken-down device identifying test on the samples, and then flagging a broken-down device.

15. The electronic device reliability measuring method of claim 14, further comprising performing an intermediate measurement and a final measurement after performing a stress test on a normal device, after the flagging of a broken-down device.

16. An electronic device reliability measuring method for performing a reliability test on electronic device samples by monitoring output voltages and output currents of the electronic device samples by
applying a single input power source to the electronic device sample or one of the electronic device samples through at least one of first switches, and
applying a single output power source to the electronic device sample or one of the electronic device samples through at least one of second switches.

17. The electronic device reliability measuring method of claim 16, wherein the electronic device samples are field effect transistors or bipolar junction transistors.

18. The electronic device reliability measuring method of claim 16, wherein the electronic device samples are diodes.

19. The electronic device reliability measuring method of claim 16, wherein the reliability test comprises a DC measurement on the samples.

20. The electronic device reliability measuring method of claim 16, wherein the reliability test comprises an RF measurement or a power characteristic measurement on the samples.
